(19) United States
(12) Patent Application Publication
(10) Pub. No.: US 2010/0292030 A1
(43) Pub. Date: Nov. 18, 2010

(54) TRANSPORT SYSTEM FOR GOLF BALLS THROUGH PLASMA FIELD

(76) Inventors: Matthew F. Hogge, Plymouth, MA (US); Vincent M. Camboni, Fall River, MA (US)

Correspondence Address: ACUSHNET COMPANY, 333 BRIDGE STREET, P. O. BOX 965, FAIRHAVEN, MA, 02719, US

(21) Appl. No.: 12/466,738

(22) Filed: May 15, 2009

(51) Int. Cl. A63B 37/00; C23C 16/56

(52) U.S. Cl. 473/374; 118/723 R

(57) ABSTRACT

An apparatus for use in transporting golf balls through a glow discharge plasma treating field, wherein the surface energy of the golf balls is increased to improve wetting ability and adhesion between layers of the golf balls. The apparatus involves a plurality of plastic open helical tubes for moving the balls such that every ball is afforded maximum exposure to the plasma field.

### FIELD OF THE INVENTION

The invention relates to an improvement in the transporting of golf balls through a plasma treating apparatus. More specifically, it relates to modifying the surface energy of golf balls to improve the wetting ability and adhesion for various coatings and inks.

### BACKGROUND OF THE INVENTION

Conventional golf balls can be divided into two general types or groups: solid balls and wound balls. The difference in play characteristics resulting from these different types of construction can be quite significant.

Balls having a solid construction are generally most popular with the average recreational golfer because they provide a very durable ball while also providing maximum distance. Solid balls are generally made with a single solid core, usually made of cross-linked rubber, which is encased by a cover material. Typically the solid core is made of polybutadiene chemically with a metal salt of an unsaturated fatty acid and/or similar crosslinking agents. Covers typically are ionomers and blends of ionomers with other thermoplastics, such as SURLYN® resins, which are ionomer resins sold commercially by E.I. DuPont de Nemours of Wilmington, Del., or IOTEK®, which is sold commercially by Exxon Corporation. The cover surfaces are formed with dimples of various numbers, sizes and patterns, which improve flight distance, control and stability. The outer surface of the ball covers usually have indicia disposed thereon and may contain an application of a paint or clear lacquer to improve appearance and protect the indicia imprinted thereon.

Solid golf balls having three or more layers are more expensive to produce, but often provide improved playing characteristics. Such balls typically have a rubber-based spherical center around which is concentrically disposed one or more intermediate layers, also known as mantle layers. One or more cover layers are typically disposed concentrically about the intermediate layer(s) similar to two-piece golf balls.

Wound balls typically have either a solid or liquid filled center around which a tensioned elastomeric material (i.e., a stretched elastic thread) is wound to form a core. The wound core is then covered with a cover material, which may be the same as those discussed above for solid golf balls but also typically include balata (trans-polyisoprene) and urethanes. However, like three-piece multilayer solid golf balls, the more complex structure of wound balls generally results in a longer manufacturing time and greater expense in the production thereof compared to a two-piece ball.

One difficulty common to preparing solid multilayer balls is that materials of an outer layer do not necessarily bond well with the materials used in the inner layer(s). The coatings are often subject to exfoliation due to strong impact with a golf club, which not only can mar the appearance of the ball, but can adversely affect the distance and stability of the ball flight. This exfoliation can be reduced by improved adhesion techniques between golf ball cover surface and coating.

In order to improve adhesive bonding between the outer surface of the cover and the applied coating, many methods have been tried and administered. One process is the flame method. Used with golf balls this has presented a problem because of the heat generated, which can scorch the ball or cause burns to the inner polymer materials. Sand blasting is another technique for roughing up the ball, but again, this can be unsatisfactory in that precisely designed and formed dimples can be damaged. One method that has helped reduce product defects of the above nature involves treating the organic cover material of the golf ball with glow discharge plasma of unpolymerizable inorganic gas to advantageously modify the surface of the cover. A coating is then applied in an apparatus adapted to expose the all entire surface of the ball to the plasma. The glow plasma can be generated by applying high voltage to a gas, such as air, oxygen, or argon, at a low temperature of about 20° C. and under vacuum in the range of 100-200 m Torr, more preferably 200 m Torr. A Plasma method is described in U.S. Pat. No. 6,869,645 issued to Brum. This method utilizes a rotating tumbler to hold and subject the golf balls to the plasma treatment. However, this method is limited to a batch type procedure, and is not viable for an open-air continuous plasma process.

Plasma treatment of various shapes and types of polymers in general is well known. Plasma treatment generally oxidizes the surface of a material being treated. For example, U.S. Pat. No. 5,387,842 discloses a steady-state, glow discharge plasma generated within the volume between a pair of parallel, insulated metal plate electrodes spaced up to 5 cm apart. The electrodes are disclosed to be located within an enclosure capable of maintaining an atmosphere other than atmospheric air, such as a noble gas, between the electrode surfaces. See also U.S. Pat. No. 5,316,739 and U.S. Pat. No. 5,098,483 (methods of treating spherical surfaces).

U.S. Pat. No. 5,414,324 discloses a similar parallel plate apparatus and process, but charges the electrodes with an impedance matching network adjusted to produce a stable, uniform glow discharge at atmospheric pressure, which is also known as corona discharge.

U.S. Pat. Nos. 5,403,453 and 5,456,972 disclose polymer materials, such as film and fabrics, that may be non-destructively surface treated to improve water wettability by exposure to glow discharge plasma sustained at substantially atmospheric pressure in a modified gas atmosphere of helium or argon.

U.S. Pat. No. 4,919,434 discloses a golf ball having a cover which includes an inner cover layer and an outer cover layer, each of which includes a thermoplastic resin. Preferably, the layers are formed of materials capable of fusion bonding with each other to properly adhere the layers together.

U.S. Pat. No. 5,286,532 discloses a method for producing golf balls by surface-treating the golf ball with atmospheric pressure plasma prior to finish coating to provide a good adhesion of the coating to the golf ball, which coating is highly resistant to discoloration and deterioration.

However, these references do not disclose methods for treating a continuous stream of golf balls by a plasma treatment in a non-vacuum open air process.

### SUMMARY OF THE INVENTION

The present invention is directed to an improved transportation system for moving golf balls during a treatment with glow discharge plasma of high intensity. The plasma is applied through a 3D open air plasma field generated by plastic surface treatment equipment. The improved apparatus utilizes an array of tubes designed in order to facilitate the golf ball movement through the plasma field. The tubes are made from a polyethylene material so as to be non-conductive and are designed with helical or “spring-like” geometry in order to maximize exposure to the plasma field.

The present invention improves upon a 3D surface treating apparatus that modifies the surface of a polymer to increase it's surface energy, thereby improving the wetting ability and adhesion of various coatings and inks. The present invention, by utilizing coiled formed tubes, allows for a continuous flow of golf balls through the plasma apparatus while insuring that the entire surface of each ball has adequate exposure to the plasma field. By a slight downward gradation of the tubes through the apparatus, the golf balls are moved through the plasma field by gravity.

### BRIEF DESCRIPTION OF THE DRAWINGS

FIG. 1 is a front view of the plasma apparatus showing a possible tube configuration tube.

FIG. 2 is an elevational side view of the apparatus showing the tubes as they are structured within the apparatus.

### DESCRIPTION OF THE PREFERRED EMBODIMENTS

There are many methods for preparing a plastic surface to improve adhesive bonding, and with golf balls it is extremely necessary to improve the wetting and adhesion of the outer surface of the cover for preparation of any applied coatings. Such methods can include flame processing, although when used with golf balls this has presented a problem because of the heat generated, which can scorch the ball or cause burns to the inner polymer materials. Sand blasting is another technique for roughing up the ball, but again, this can be unsatisfactory. One method that has been introduced to help reduce product defects is the heating of the organic cover material of the golf ball with glow discharge plasma of unpolymerizable inorganic gas to advantageously modify the surface of the cover. A coating is then applied in an apparatus adapted to expose the all entire surface of the ball to the plasma. The glow plasma can be generated by several methods and currently the most popular method is by applying high voltage to a gas, such as air, oxygen, or argon, at a low temperature of about 20° C. and under vacuum in the range of 100-200 m Torr, more preferably 200 m Torr as described in a commonly owned U.S. Pat. No. 6,869,645. This method has been successfully used to treat golf ball surfaces but, until the present invention, these methods have required a vacuum atmosphere and are strictly limited to batch processes. Batch processes are counter-productive to present day golf ball manufacturing processes.

It has now been discovered that multilayer golf balls, i.e., those having two or more layers, may need improved bonding between the layers, and the bonding may be achieved by treating a the surface of the layer. The treated surface is ultimately disposed within the golf ball with the cover having a plurality of dimples that is disposed about the surface. The treatment may include any chemical or mechanical process that improves or facilitates adhesion of the treated surface to an adjacent surface, typically by low pressure plasma treatment, corona discharge treatment, chemical etching, or the like. Preferably, the treatment includes at least one of low pressure plasma treatment. This advantageously results, for example, in a cover and core having reduced delamination, even upon repeated impact, due to improved bonding there between that inhibits degradation of the cover and preferably inhibits or prevents delamination or tear of a bonded, i.e., treated, layer(s). Golf balls prepared according to the present invention are thus provided with improved durability and/or playing characteristics to inhibit degradation when struck by a club.

It is to be appreciated that the apparatus and method of plasma treatment of the present invention may apply to the treatment of golf ball component surfaces which may include at least one of a golf ball center, or an intermediate layer, the outermost intermediate layer that forms an interface between the core, and the cover layer. However, for purposes of simplification, the present invention will only describe the apparatus for treating a golf ball cover surface. Without being bound by theory, it is believed that plasma treatment removes low molecular weight portions of the material to be treated by oxidation thereof and modifies the surface chemistry to promote adhesion on an atomic level.

Plasma treatment of the golf ball surface typically provides using a gas at a low temperature from about 0° C. to about 100° C., preferably from about 20° C. to about 90° C., more preferably from about 30° C. to about 80° C. Such low temperatures advantageously inhibit undesired modification or thermal degradation of the golf ball surface being treated. This surface typically contains materials that may be degraded or modified at higher temperatures.

Any gas suitable for plasma treatment may be used. Gases typically used in the plasma treatment include air, oxygen, nitrogen, argon, ammonia, or helium. Preferably, the gas is oxygen or air, and more preferably the gas is oxygen. The plasma treatment according to the invention should be conducted for a suitable amount of time sufficient to increase the adhesiveness of the surface being treated. Preferably, however, the treatment time is less than about 30 minutes, more preferably less than about 20 minutes, and most preferably less than about 10 minutes.

Any source of energy is suitable for facilitating the plasma treatment according to the invention. Preferably, however, the energy source includes direct electrical current, whether it be low frequency electrical current, or high frequency electrical current. As stated above, radio frequency may be used provided it be radio frequency energy of greater than about 1 kHz, preferably greater than about 1 MHZ, and more preferably from about 1 MHz to 50 MHz to charge the gas for plasma treatment. An exemplary radio frequency is 13.56 MHZ in which the plasma treatment is provided to the surface of a portion of the golf ball being treated.

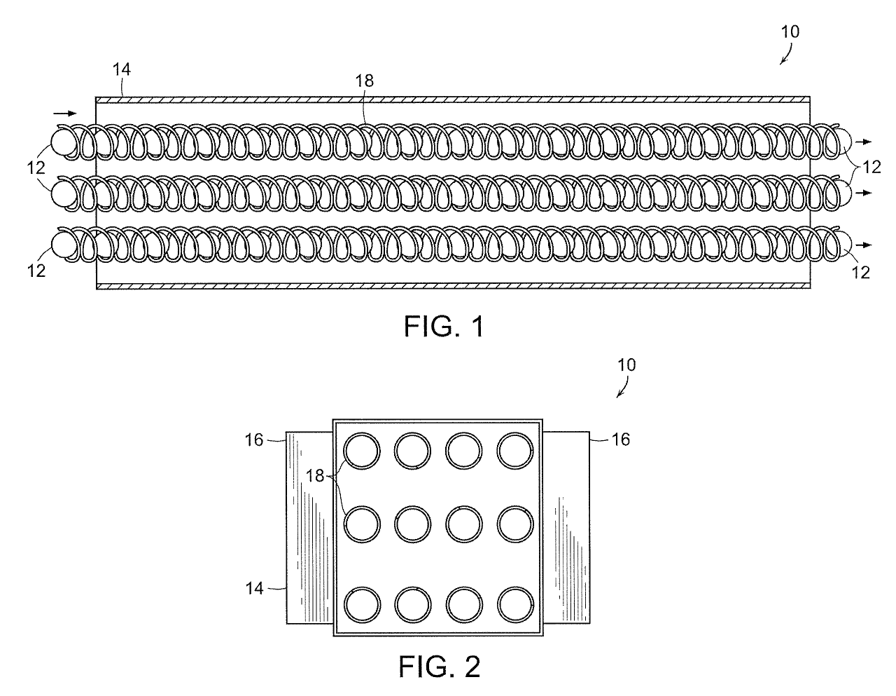

Referring to FIGS. 1 and 2, there is shown an apparatus 10 of the present invention that applies plasma heat treatment to golf balls 12 introduced into the apparatus by either automatic or manual means. FIG. 1 shows one embodiment of the invention wherein twelve (12) tubes are positioned within the plasma apparatus 10, such as the LECTRO-TREAT which is manufactured and sold by Lectro Engineering of St. Louis, Mo. The apparatus 10, as manufactured, comprises a rectangular tunnel 14 wherein there is generated three-dimensional (3D) “open-air” plasma by the use of two sets of parallel plate capacitors 16 affixed to the sides of the apparatus 14. All exposed surfaces of articles to be treated are affected by the plasma field as they pass through the tunnel 14. As manufactured by Lectro Engineering, the articles to be plasma treated are moved through the tunnel by conveyor belt systems, and facilitate the treatment of parts of varying size and geometry. The tunnel dimensions of the standard Lectro-Treat system are approximately 12 inches high (H) by 12 inches wide (W) by 72 inches long (L). However, these dimensions are only illustrative. FIGS. 1 and 2 are not drawn to scale but are provided to present the theory of the present invention. Although plasma treatment of plastic articles, as practiced by the Lecro-Treat apparatus has been efficient for other articles, it has been shown that processing golf balls through this machine with the standard conveyor system is problematic and inefficient for many reasons. With the current conveyor system, golf balls would be placed in one layer on the conveyor system, thereby utilizing only about 14% of the total volume of the Lectro-Treat capacity. This layer cannot be tightly packed, because the golf balls need to roll freely in order to expose all surfaces to the plasma. It is problematic to stack layers of golf ball, say in a perforated basket, as the point contacts between balls would prevent total exposure of the ball surface to the plasma. The present invention solves this problem by redesigning the tunnel and installing an array of golf ball transport tubes 18 through the Lectro-Treat tunnel. These tubes 18 would have a slight downward gradation in order for gravity to facilitate the rolling of the golf balls. A preferred design of the tubes 18 is that they are of a helical or “spring-like” structure (i.e. “Slinky” toy) in order to expose the entire surface of the golf ball 12 to the plasma charge as they roll through the helical tubes 18. The preferred material for the tubes is ultra high molecular weight (UHMW) polyethylene, although any structurally sound polymer material could be used as the material for tube fabrication, so long as the material is non-conductive to electricity. The actual number of the tubes can vary, but for the discussion presented herein only twelve tubes are disclosed and discussed. Since a golf ball has a diameter of approximately 1.68 inches, tubes 18 should have an inside diameter of about 1.80 inches and an outside diameter of about 2.0 inches. The golf balls may be fed into the tubes by manual or automated methods and would fill the tubes, wherein their residence time within the Lectro-Treat can be controlled by the rate at which golf balls were allowed to exit the tubes. Preferably a metered automated method is used to precisely control the rate and exposure time in which the golf balls would be in the tunnel.

As used herein, the terms “cover” and “cover layer” refer to the outermost layer of a golf ball that contains dimples. Any desired type of coating, such as paint, lacquer, or the like, may be disposed about the cover layer, i.e., about the golf ball, in any manner known to those of ordinary skill in the art. As used herein, the term “core” means the one or more layers of a golf ball about which the cover layer is disposed. As used herein, the outer, and in particular the outermost, core layers may be comprised of either thermoset rubber compositions, thermoplastic resins, or the like.

Golf balls of the present invention may utilize cover layers having a Shore D hardness of less than about 75. In a preferred embodiment, the cover layer exhibits a Shore D hardness between about 40 to 65. The cover includes any suitable material known to those of ordinary skill in the art, such as a thermoset material as noted above that is selected from the group of polyisoprene, polybutadiene, polyurethane, polysulfide rubber, polyurea, polyester, epoxy resin, and mixtures thereof. In a preferred embodiment, the cover includes a thermoplastic material of a material selected from the group of a polyolefin, polyamide, polyester, polytri-methylene terephthalate, copoly(ether-ester), copoly(ester-ester), polyamide, copoly(urethane-ester), copoly(urethane-ether), polyacrylate, polystyrene, styrene-butadiene-styrene copolymer, styrene-ethylene-butylene-styrene copolymer, polypropylene, ethylene-propylene-diene terpolymer or ethylene-propylene vulcanized copolymer rubber, polycarbonate, and mixtures thereof.

In a preferred embodiment, the ball surface treating is accomplished by applying a gas excited to a plasma state to the surface being treated. In a more preferred embodiment, the gas is excited to the plasma state by RF energy, electron beam, microwave, electrical discharge, or other suitable methods known to those of ordinary skill in the art. Indeed, a primary or secondary method may be used. Primary methods include those where the surface to be treated is placed in the plasma field, while secondary methods include those where the plasma is blown or otherwise moved onto the surface to be treated.

One embodiment of the golf ball prepared according to the invention, may be provided with a construction having a thin layer of a relatively soft thermoset material formed from a castable reactive liquid. As used herein, the term “thermoset” material refers to a crosslinked polymer that is a reaction product of two or more precursor materials, e.g., polyurethane.

Actually, golf balls prepared according to the invention may be made of any materials capable of being treated according to the invention, preferably olefinic polymers, ionomeric polymers, or both, as well as other low surface energy materials. For example, SURLYN® materials typically have a surface energy of about 34 dyne/cm². In a preferred embodiment of the invention, the surface energy of a layer is increased by at least about 2 dyne/cm², preferably by at least about 5 dyne/cm², and more preferably by at least about 10 dyne/cm², after treatment according to the invention to facilitate bonding with an adjacent layer. Examples of suitable materials are discussed below in connection with a preferred embodiment of the invention, which materials can of course be used in any combination to provide other suitable golf balls according to the invention.

In one particular embodiment, the golf balls prepared according to the invention are multilayer golf balls including a core and a cover layer. The core may be solid, hollow, or fluid-filled. Specifically, it has been determined that the cover layer should have a thickness of about 0.045 inches or less, preferably from about 0.007 and 0.04 inches. Most preferably, this cover thickness is from about 0.014 to 0.03 inches.

The cover layer of this embodiment can include any suitable thermoset material formed from a reactive liquid material. Suitable thermoset materials include polyisoprene, polybutadiene, polyurethane, styrene-butadiene-styrene rubber, polysulfide rubber, polyurea, polyester, epoxy resins, and any copolymers or mixtures thereof (e.g., urethane ionomer, urethane epoxy). The preferred materials for the cover layer include, but are not limited to, castable thermoset urethanes, including thermoset urethane ionomers and thermoset urethane epoxies. Examples of suitable urethane ionomers are disclosed in U.S. Pat. No. 5,692,974. Several other suitable urethanes are disclosed in U.S. Pat. Nos. 5,334,673; 5,484,870; 5,733,428; 5,888,437; and 5,908,358. The disclosure of each of these urethane patents is incorporated herein in its entirety by express reference thereto.

Thermoset polyurethanes and urethanes are particularly preferred for use in the cover layer for this embodiment of the invention. Polyurethane is a product of a reaction between a polyol or diamine, and a diisocyanate.

Conventionally, thermoset polyurethanes are prepared using a diisocyanate, such as 2,4-toluene diisocyanate (TDI) or methylenebis-(4-cyclohexyl isocyanate) (HMDI) and a polyol which is cured with a polyamine, such as methylenedianiline (MDA), or a trifunctional glycol, such as trimethylol propane, or tetrafunctional glycol, such as N,N,N′,N′-tetrakis(2-hydroxypropyl)ethylenediamine. One preferred cover formulation is a reaction product of 4,4′-diphenylmethane-diisocyanate (MDI), polytetramethylene ether glycol (PTMEG Polyol), and polytetramethyleneoxide-di-p-aminobenzoate (commercially available, for example, as POLAMINE 250 or VERSALINK P-250). The present invention is not, however, limited to just these specific types of thermoset polyurethanes. Quite to the contrary, any suitable thermoset polyurethane may be employed to form the cover layer of this or any other embodiment of the invention.

The following thermoplastic material(s) are preferably included in the cover layer having a plurality of dimples. Particularly suitable thermoplastic materials for the cover include ionomer materials of a polyolefin, polyamide, polyester, polytrimethylene terephthalate, copoly(ether-ester), copoly(ester-ester), polyamide, polyether, copoly(urethane-ester), copoly(urethane-ether), polyacrylate, polystyrene, styrene-butadiene-styrene copolymer, styrene-ethylene-butylene-styrene copolymer, polypropylene, ethylene-propylene-diene terpolymer or ethylene-propylene dynamically vulcanized copolymer rubber, polycarbonate, mixtures thereof, and the like. Preferably, ionomers usefull in the invention are copolymers of an olefin and an .alpha.,.beta.-ethylenically unsaturated carboxylic acid in which at least a portion of the carboxylic acid groups have been neutralized with a metal ion, typically sodium, lithium, magnesium, or zinc. More preferably, the olefin is ethylene, and the .alpha.,.beta.-ethylenically unsaturated carboxylic acid is acrylic or methacrylic acid, where the metal ion is zinc, sodium, magnesium, manganese, calcium, lithium or potassium.

The manner in which the ionomers used in the cover layer are made is well known in the art as described in, e.g., U.S. Pat. No. 3,262,272, which is incorporated herein in its entirety by express reference thereto. Such ionomer resins are commercially available from DuPont Co. of Wilmington, Del. under the tradename SURLYN® and from Exxon under the tradename IOTEK®. However, the materials are not limited to ionomer resins. Any suitable material available to those of ordinary skill in the art can be employed in this layer, such as thermoplastic or thermoset polyurethanes, thermoplastic or thermoset polyetheresters or polyetheramides, thermoplastic or thermoset polyester, a vulcanized elastomer, styrene-butadiene elastomer, a metallocene, maleic anhydride grafted styrene-ethylene-butylene-styrene copolymers, a polyamide, acrylonitrile butadiene-styrene copolymer, or blends thereof.

While it is apparent that the illustrative embodiments of the invention herein discloses fulfills the objective stated above, it will be appreciated that numerous modifications and other embodiments and test methods may be devised by those skilled in the art. Therefore, it will be understood that the appended claims are intended to cover all such modifications and embodiments which come within the spirit and scope of the present invention.

What is claimed is:

1. An apparatus for treating a surface of a golf ball comprising:
a support structure for a treatment tunnel, the tunnel having inlet and exit openings;
a plurality of parallel plate capacitors juxtaposed against lateral sides of the treatment tunnel;
a plurality of transport tubes housed within the tunnel and having a slight downward gradation from the inlet opening to the exit opening;
an electric source for applying high voltage across the capacitors in order to generate an open-air plasma field within the tunnel; and
a continuous rolling feed of golf balls through the plurality of transport tubes, the balls rolling to insure an even distribution of the plasma field to the golf ball surfaces,
wherein, the golf balls are evenly exposed to the plasma field to increase their surface energy and therein improving their wetting ability and adhesion for various coatings and inks.

2. The apparatus of claim 1, wherein the transport tubes are of a helical or coiled structure.

3. The apparatus of claim 2, wherein the transport tubes have an outside diameter of about 2 inches.

4. The apparatus of claim 3, wherein the thickness of the tube is less than 0.10 inches.

5. The apparatus of claim 2, wherein the tubes are formed from an electrically non-conductive material.

6. The apparatus of claim 5, wherein the tubes are made of ultra high molecular weight polyethylene.

7. The apparatus of claim 1, wherein the treatment tunnel is of a rectangular shape and about 72 inches in length.

8. The apparatus of claim 1, wherein the number of transport tubes is twelve.

9. The apparatus of claim 1, wherein there are two pairs of parallel plate capacitors.

10. The apparatus of claim 1, wherein the surface energy of the golf balls is increased by at least 10 dyne/cm².

11. The apparatus of claim 1, wherein the plasma field is generated by the glow discharge of an unpolymerizable inorganic gas selected from the group consisting of air, oxygen, or argon.

12. A golf ball comprising: a core; an inner cover layer comprising an ionomer resin, wherein the outer surface of said inner cover layer is plasma treated to increase the adhesion thereof by raising the surface energy of the inner cover layer by at least 10 dyne/cm².

13. The golf ball of claim 12, wherein the outer cover layer comprises urethane.

14. The golf ball of claim 12, wherein the outer cover layer has a thickness of less than about 0.045 inches.

15. The golf ball of claim 14, wherein the outer cover layer has a thickness of about 0.014 inches to about 0.03 inches.

16. The golf ball of claim 12, wherein the inner cover layer is a thermoplastic material having a shore D hardness of about 50 or more, and the outer cover layer is a thermoset material.

17. The golf ball of claim 16, wherein said outer cover layer has a shore D hardness between 40 to about 65.
